(19) United States
(12) Patent Application Publication
(10) Pub. No.: US 2026/0122865 A1
(43) Pub. Date: Apr. 30, 2026

(54) PUMPED TWO-PHASE COOLING SYSTEM

(71) Applicant: Hitachi Energy Ltd, Zürich (CH)

(72) Inventors: Pascal Lutz, Neuenhof (CH); Stefanie Heinig, Basel (CH); Thomas Schwarzmaier, Wettingen (CH); Remo Baumann, Lenzburg (CH)

(21) Appl. No.: 19/163,281

(22) PCT Filed: Mar. 9, 2023
(86) PCT No.: PCT/EP2023/055955

§ 371 Date: Sep. 8, 2025

(51) Int. Cl. H05K 7/20

(52) U.S. Cl. CPC H05K 7/20927

(57) ABSTRACT

The invention relates to a pumped two-phase cooling system that includes a two-phase working fluid circuit, having a first circuit section for guiding a first portion of the working fluid to a preheater assembly the first portion in the first circuit section having first thermal characteristics, a second circuit section for guiding a second portion of the working fluid to the preheater assembly, the second portion in the second circuit section having second thermal characteristics, and a third circuit section for guiding a third portion of the working fluid from the preheater assembly to at least one evaporator, the third portion in the third circuit section having third thermal characteristics based on the first and second thermal characteristics.

### CROSS REFERENCE TO RELATED APPLICATIONS

This application is a 35 U.S.C. § 371 national stage application of International Application No. PCT/EP2023/055955 filed on Mar. 9, 2023, the disclosures and content of which are incorporated by reference herein in their entirety.

### BACKGROUND

The present disclosure relates to a pumped two-phase cooling system.

A pumped two-phase cooling system utilizes the latent heat of vaporization of a working fluid to remove thermal energy from a component to be cooled.

FIG. 1 schematically illustrates a known pumped two-phase cooling system. The system comprises a working fluid circuit 200 for guiding a two-phase working fluid.

The system further comprises a pump 300 for pumping the working fluid through the circuit 200. The system further comprises a preheater 400, an evaporator 500, a condenser 600, and a reservoir 100 also sometimes referred to as an accumulator. The circuit 200 connects these devices 400, 500, 600, 100 to allow the working fluid to flow through the evaporator 500 and subsequently through the condenser 600. The pump 300 pumps the working fluid through the preheater 400, the evaporator 500 and the condenser 600 in that order.

The evaporator 500 is configured to cool a thermal energy dissipating component, for example a power electronic device. To this end, the evaporator 500 is arranged and designed to absorb heat from the respective component to be cooled.

The preheater 400 increases the temperature of the working fluid which enters the preheater 400 in its liquid phase, up to its saturation temperature, i.e. up to its optimal operating point. Accordingly, the working fluid enters the evaporator 500 at least essentially at its saturation temperature. Therefore, the heat or thermal energy absorbed by the working fluid flowing through the evaporator 500 causes the working fluid to partially evaporate. Therefore, the working fluid leaving the evaporator 500 is partly in its liquid phase and partly in its gaseous phase.

Subsequently, the working fluid is guided by the circuit 200 to the condenser 600 where heat is removed from the working fluid so that it is returning to its liquid phase. The condenser 600 disperses the heat to the surrounding environment.

The reservoir 100 is configured to balance the system. To this end, the reservoir 100 stores excess working fluid and compensates for volume changes.

By using the latent heat of the working fluid, it can be achieved that the two-phase cooling system in principle requires less pumping power compared to a single-phase cooling system under otherwise identical conditions.

However, the preheater 400 still requires a certain amount of electric energy to generate a corresponding heat. This leads to a limited efficiency of the system and a limited reliability.

Therefore, there is a need for an improved two-phase cooling system, particularly for a two-phase cooling system having improved features regarding efficiency and reliability.

U.S. Pat. No. 10,458,665 B2 relates to a passive liquid collecting device which has a reservoir with an outlet and one or more rigid structures within the reservoir. The rigid structures are configured to collect a liquid and direct the liquid to the outlet. Porous capillary media are supported by the rigid structures. A thermal control loop is also described. The thermal control loop circulates a refrigerant to remove heat from objects.

U.S. Pat. No. 6,866,092 B1 relates to various techniques for improving airtight two-phase heat-transfer systems employing a fluid to transfer heat from a heat source to a heat sink while circulating around a fluid circuit, the maximum temperature of the heat sink not exceeding the maximum temperature of the heat source. The properties of those improved systems include (a) maintaining, while the systems are inactive, their internal pressure at a pressure above the saturated-vapor pressure of their heat-transfer fluid; and (b) cooling their internal evaporator surfaces with liquid jets.

U.S. Pat. No. 10,436,521 B2 relates to a system which includes a pump, an evaporator, a condenser, an accumulator, a pump bypass line, a first valve, and a second valve. The system may operate in a powered-pump mode, in which the pump drives fluid circulation, the first valve prevents fluid circulation through the pump bypass line, the pump pumps liquid from the accumulator to the evaporator, gas exiting the evaporator flows to the condenser, liquid exiting the evaporator flows through the second valve to the accumulator, and liquid exiting the condenser flows to the accumulator. The system may operate in a passive-capillary mode, in which capillary pressure in the evaporator drives fluid circulation, the first valve prevents fluid circulation through the pump, liquid flows from the accumulator, through the pump bypass line, and to the evaporator, gas exiting the evaporator flows to the condenser, the second valve is closed, and liquid exiting the condenser flows the accumulator.

### SUMMARY

According to the present disclosure a pumped two-phase cooling system is provided that comprises a two-phase working fluid circuit. The circuit has a first circuit section for guiding a first portion of the working fluid to a preheater assembly. The first portion in the first circuit section has first thermal characteristics. The circuit further has a second circuit section for guiding a second portion of the working fluid to the preheater assembly. The second portion in the second circuit section has second thermal characteristics. The circuit further comprises a third circuit section for guiding a third portion of the working fluid from the preheater assembly to at least one evaporator. The third portion in the third circuit section has third thermal characteristics based on the first and second thermal characteristics.

By providing for the second circuit section, it is possible to supply additional thermal energy to the working fluid in the first circuit section, i.e. before it enters the evaporator. In this way, it is possible to eliminate the need for a preheater that requires external energy or at least to operate the system using a preheater assembly that requires less energy as compared to a preheater of a cooling system according to the above-mentioned prior art. In other words, the preheater assembly of the cooling system according to the present description may require no or at least less external energy as compared to prior art.

Accordingly, less energy is in principle required to operate the cooling system. Therefore, the two-phase cooling system may show an improved efficiency and consequently, an improved reliability.

Various embodiments may implement the following features:

The preheater assembly may be configured to heat the working fluid to its saturation temperature or at least nearly to its saturation temperature. This is generally advantageous in respect of the cooling capacity of the system. Particularly, the preheater assembly may be configured to heat the working fluid in such a way that its temperature is at or nearly at its saturation temperature when it enters the evaporator.

The term “a temperature nearly to the saturation temperature” is intended to describe a temperature that is within a certain temperature interval including the saturation temperature. The temperature interval may be 6 K or 5 K or 4 K or 3 K or 2 K.

The preheater assembly may comprise an electric heating device for heating the working fluid. In this way, for example, the time between starting up the system and reaching the optimum temperature of the working fluid upstream of the evaporator can be kept particularly short.

The circuit may further comprise a fourth circuit section for guiding a fourth portion of the working fluid from the at least one evaporator to a condenser. The second circuit section may be connected to the fourth circuit section. Upon exiting the evaporator, i.e. in the fourth circuit section, the working fluid has a comparatively large amount of thermal energy. This thermal energy can thus be used particularly advantageously to be fed to the preheater assembly by the provision of the connection between the fourth circuit section and the second circuit section.

Accordingly, the thermal energy that is “already in the system” can be used by the preheater assembly. The second circuit section can be used to branch off some of the thermal energy of the working fluid in the fourth circuit section and route it back to the preheater assembly, particularly in a controlled way, where it is mixed with a “main flow” in form of the flow of the first portion of the working fluid in the first circuit section to heat it up.

The circuit may further comprise a fifth circuit section for guiding a fifth portion of the working fluid from the condenser to the first circuit section, wherein the first portion of the working fluid originates from the fifth portion. In this way a closed circuit or closed loop for guiding the working fluid is provided.

The fifth circuit section may comprise a reservoir for the working fluid. The reservoir may be configured to balance the system, e.g. by storing excess working fluid and compensating for volume changes of the working fluid.

The system may further comprise a pump for pumping the working fluid through the two-phase working fluid circuit. The pump may be provided for example at the fifth circuit section, e.g. between the reservoir and the first circuit section.

The thermal characteristics may include temperature and/or pressure and/or thermal energy. The first thermal characteristics may comprise that the working fluid is in a liquid phase, the second thermal characteristics may comprise that the working fluid is partly in a liquid phase and partly in a gaseous phase, and the third thermal characteristics may comprise that the working fluid is in a liquid phase. The first thermal characteristics may be different from the third thermal characteristics. Specifically, the third thermal characteristics may comprise that the working fluid contains more energy compared to the first thermal characteristics.

The system may further comprise a valve disposed within the second circuit section. The valve makes it possible to influence an intensity of a flow (i.e. a volumetric flow rate) of the working fluid through the second circuit section. In this way it is possible to influence how much thermal energy is supplied to the preheater assembly via the working fluid flowing through the second circuit section. The valve may be a one way valve.

The valve may be configured to allow the working fluid to flow from the fourth circuit section via the second circuit section to the preheater assembly and further being configured to prevent the working fluid from flowing from the preheater assembly via the second circuit section to the fourth circuit section. In particular, this at least essentially prevents thermal energy from being extracted from the working fluid in the first circuit section before it subsequently enters the evaporator.

The valve may be configured to control a flow of the working fluid from the fourth circuit section via the second circuit section to the preheater assembly. In this way it is possible to quantitively determine the amount of thermal energy that is fed to the first portion of the working fluid, i.e. to the working fluid in the first circuit section.

The system may further comprise at least one temperature and/or pressure sensor device for measuring a temperature and/or a pressure of the working fluid. The at least one temperature and/or pressure sensor device may be disposed within the first circuit section and/or within the third circuit section. A temperature or pressure sensor may also or alternatively be provided in the second circuit section. A temperature or pressure value measured by the temperature and/or pressure sensor device can be particularly advantageously used for an improved control of the flow of the working fluid through the second circuit section.

To this end, for example the valve may be configured to be operated under use of a temperature and/or pressure information generated or measured by the temperature and/or pressure sensor device.

The preheater assembly may comprise a junction configured to allow the first portion of the working fluid to mix with the second portion of working fluid. In this way, a structurally simple and thus particularly reliable configuration for mixing of the first portion of the working fluid with the second portion of the working fluid is made possible.

The preheater assembly may further comprise a coupling circuit section connecting the junction to the third circuit section. The coupling circuit section may be for example tube-shaped.

The electric heating device of the preheater assembly-if provided-may be disposed at the coupling circuit section.

The preheater assembly may further comprise a heat exchanger connected to the first circuit section and to the second circuit section and being configured to exchange heat between the first portion of the working fluid and the second portion of the working fluid. The heat exchanger allows for an improved control of heat exchange between the working fluid originating from the first circuit section and the working fluid originating from the second circuit section. The heat exchanger may be configured to exchange heat between the first portion of the working fluid and the second portion of the working fluid without exchanging working fluid.

Particularly, the configuration may be such that the working fluid condenses in the heat exchanger and gives its thermal energy to the “main fluid” in form of the flow of the first portion of the working fluid in the first circuit section. Subsequently, the working fluid will be mixed with the “main flow” downstream of the heat exchanger.

The system may further comprise an extension circuit section for guiding the working fluid originating from the second circuit section, after it has passed through the heat exchanger, to a coupling circuit section connecting the first circuit section to the third circuit section.

The system may further comprise an auxiliary pump for pumping the working fluid from the extension circuit section to the third circuit section. The auxiliary pump is needed depending on the system design and pressure level. The auxiliary pump, however, needs much less energy compared to a preheater according to prior art as described above.

The preheater assembly may further comprise a heat exchanger connected to the second circuit section and to a coupling circuit section connecting the first circuit section to the third circuit section. The heat exchanger may be configured to exchange heat between the working fluid originating from the second circuit section and the working fluid within the coupling circuit section.

Here, the working fluid is mixed with the “main flow” upstream of the heat exchanger.

The system may further comprise an extension circuit section for guiding the working fluid originating from the second circuit section, after it has passed through the heat exchanger, to the coupling circuit section at a point between the first circuit section and the heat exchanger. The point may be between the first circuit section and the pump or between the pump and the preheater assembly.

Alternatively, the extension circuit section may be configured to guide the working fluid originating from the second circuit section, after it has passed through the heat exchanger, to the reservoir.

The system may further comprise an auxiliary pump for pumping the working fluid from the extension circuit section to the coupling circuit section or to the reservoir.

According to an alternative or additional aspect of the present disclosure, a pumped two-phase cooling system is provided that comprises a reservoir, containing a two-phase working fluid, an evaporator, a condenser, a two-phase working fluid circuit connecting the reservoir, the evaporator and to the condenser and configured to allow the working fluid to flow through the evaporator and through the condenser. The system further comprises a pump, configured to pump the working fluid through the circuit, and a preheater assembly, disposed and configured to preheat the working fluid before entering the evaporator. The circuit comprises a first circuit part configured to allow the working fluid to flow from the evaporator to the condenser, a second circuit part configured to allow the working fluid to flow from the condenser to the evaporator, and a third circuit part connecting the first circuit part to the second circuit part, bypassing the condenser.

In particular, the present disclosure comprises the following aspects:
1. Pumped two-phase cooling system, comprising
   a two-phase working fluid circuit, having
      a first circuit section for guiding a first portion of the working fluid to a preheater assembly, the first portion in the first circuit section having first thermal characteristics,
      a second circuit section for guiding a second portion of the working fluid to the preheater assembly, the second portion in the second circuit section having second thermal characteristics, and
      a third circuit section for guiding a third portion of the working fluid from the preheater assembly to at least one evaporator, the third portion in the third circuit section having third thermal characteristics based on the first and second thermal characteristics.
2. Pumped two-phase cooling system of aspect 1, the preheater assembly being configured to heat the working fluid to its saturation temperature or at least nearly to its saturation temperature.
3. Pumped two-phase cooling system of aspect 2, the preheater assembly comprising an electric heating device for heating the working fluid.
4. Pumped two-phase cooling system of any of the preceding aspects, the two-phase working fluid circuit further comprising a fourth circuit section for guiding a fourth portion of the working fluid from the at least one evaporator to a condenser, the second circuit section being connected to the fourth circuit section.
5. Pumped two-phase cooling system of aspect 4, the two-phase working fluid circuit further comprising a fifth circuit section for guiding a fifth portion of the working fluid from the condenser to the first circuit section, wherein the first portion of the working fluid originates from the fifth portion.
6. Pumped two-phase cooling system of aspect 5, the fifth circuit section comprising a reservoir for the working fluid.
7. Pumped two-phase cooling system of any of the preceding aspects, further comprising a pump for pumping the working fluid through the two-phase working fluid circuit.
8. Pumped two-phase cooling system of any of the preceding aspects, the first thermal characteristics comprising that the working fluid is in a liquid phase, the second thermal characteristics comprising that the working fluid is partly in a liquid phase and partly in a gaseous phase, and the third thermal characteristics comprising that the working fluid is in a liquid phase.
9. Pumped two-phase cooling system of any of the preceding aspects, further comprising a valve disposed within the second circuit section.
10. Pumped two-phase cooling system of aspect 9, comprising the features of aspect 4, the valve being configured to allow the working fluid to flow from the fourth circuit section via the second circuit section to the preheater assembly and further being configured to prevent the working fluid from flowing from the preheater assembly via the second circuit section to the fourth circuit section.
11. Pumped two-phase cooling system of aspect 9 or 10, the valve being configured to control a flow of the working fluid from the fourth circuit section via the second circuit section to the preheater assembly.
12. Pumped two-phase cooling system of any of the preceding aspects, further comprising at least one temperature and/or pressure sensor device for measuring a temperature and/or a pressure of the working fluid, the at least one temperature and/or pressure sensor device being disposed within the first circuit section and/or within the third circuit section.
13. Pumped two-phase cooling system of any of the preceding aspects, comprising the features of aspects 9 and 12, wherein the valve is configured to be operated under use of a temperature and/or pressure information generated by the temperature and/or pressure sensor device.
14. Pumped two-phase cooling system of any of the preceding aspects, the preheater assembly comprising a junction configured to allow the first portion of the working fluid to mix with the second portion of working fluid.
15. Pumped two-phase cooling system of aspect 14, the preheater assembly further comprising a coupling circuit section connecting the junction to the third circuit section.
16. Pumped two-phase cooling system of aspect 15, comprising the features of aspect 3, the electric heating device disposed at the coupling circuit section.
17. Pumped two-phase cooling system of any of aspects 1 to 13, the preheater assembly further comprising a heat exchanger connected to the first circuit section and to the second circuit section and being configured to exchange heat between the first portion of the working fluid and the second portion of the working fluid.
18. Pumped two-phase cooling system of aspect 17, further comprising an extension circuit section for guiding the working fluid originating from the second circuit section, after it has passed through the heat exchanger, to a coupling circuit section connecting the first circuit section to the third circuit section.
19. Pumped two-phase cooling system of aspect 18, further comprising an auxiliary pump for pumping the working fluid from the extension circuit section to the third circuit section.
20. Pumped two-phase cooling system of any of aspects 1 to 13, the preheater assembly further comprising a heat exchanger connected to the second circuit section and to a coupling circuit section connecting the first circuit section to the third circuit section, the heat exchanger being configured to exchange heat between the working fluid originating from the second circuit section and the working fluid within the coupling circuit section.
21. Pumped two-phase cooling system of aspect 20, further comprising an extension circuit section for guiding the working fluid originating from the second circuit section, after it has passed through the heat exchanger, to the coupling circuit section at a point between the first circuit section and the heat exchanger.
22. Pumped two-phase cooling system of aspect 21, further comprising an auxiliary pump for pumping the working fluid from the extension circuit section to the coupling circuit section.
23. Pumped two-phase cooling system of aspect 20, further comprising an extension circuit section for guiding the working fluid originating from the second circuit section, after it has passed through the heat exchanger, to the reservoir.
24. Pumped two-phase cooling system of aspect 23, further comprising an auxiliary pump for pumping the working fluid from the extension circuit section to the reservoir.
25. Pumped two-phase cooling system, preferably according to any one of the preceding aspects, comprising
   a reservoir, containing a two-phase working fluid,
   an evaporator,
   a condenser,
   a two-phase working fluid circuit connecting the reservoir, the evaporator and the condenser and configured to allow the working fluid to flow through the evaporator and through the condenser,
   a pump, configured to pump the working fluid through the circuit,
   a preheater assembly, disposed and configured to preheat the working fluid before entering the evaporator,
   the circuit comprising
      a first circuit part configured to allow the working fluid to flow from the evaporator to the condenser,
      a second circuit part configured to allow the working fluid to flow from the condenser to the evaporator, and
      a third circuit part connecting the first circuit part to the second circuit part, bypassing the condenser.
26. Pumped two-phase cooling system of aspect 25, the pump being configured to pump the working fluid through the condenser and the reservoir, in this order.
27. Pumped two-phase cooling system of any of aspects 25 to 26, the pump being configured to pump the working fluid through the preheater and the evaporator, in this order.
28. Pumped two-phase cooling system of any of aspects 25 to 27, the third circuit part constituting a return line for allowing the working fluid to return from the first circuit part to the second circuit part upstream of the evaporator.
29. Pumped two-phase cooling system of any of aspects 25 to 28, the third circuit part being connected to the second circuit part at a connection so as to allow a portion of the working fluid to flow from the third circuit part into the second circuit part at the connection.
30. Pumped two-phase cooling system of aspect 29, further comprising a mixing arrangement disposed at the connection and being configured to control a mixing ratio between a flow of working fluid flowing from the third circuit part into the second circuit part and a further flow of working fluid flowing from a first portion of the second circuit part upstream of the connection into a second portion of the second circuit part downstream of the connection.
31. Pumped two-phase cooling system of any of aspects 25 to 30, the third circuit part being connected to the second circuit part at the preheater assembly.
32. Pumped two-phase cooling system of any of aspects 25 to 31, further comprising a valve disposed within the third circuit part.
33. Pumped two-phase cooling system of aspect 32, the valve being configured to allow the working fluid to flow from the first circuit part via the third circuit part to the second circuit part and further being configured to prevent the working fluid from flowing from the second circuit part via the third circuit part to the first circuit part.
34. Pumped two-phase cooling system of any of aspects 25 to 33, further comprising at least one temperature and/or pressure sensor device disposed within the second circuit part or the third circuit part and being configured to measure a temperature or pressure of the working fluid.
35. Pumped two-phase cooling system of aspect 34, the at least one temperature and/or pressure sensor device being disposed between the pump and the preheater assembly or between the preheater assembly and the evaporator.
36. Pumped two-phase cooling system of aspect 35, comprising at least two temperature and/or pressure sensor devices, a first one of the at least two temperature and pressure sensor devices being disposed between the pump and the preheater assembly, and a second one of the at least two temperature and/or pressure sensor devices being disposed between the preheater assembly and the evaporator.
37. Pumped two-phase cooling system of any of aspects 25 to 36, further comprising a heat exchanger disposed and configured to exchange heat between at least a portion of the working fluid within the third circuit part and at least a further portion of the working fluid within the second circuit part.
38. Pumped two-phase cooling system of aspect 37, the heat exchanger being disposed adjacent to or within the preheater assembly.
39. Pumped two-phase cooling system of aspect 37 or 38, further comprising a further pump configured to pump the working fluid from the third circuit part to the second circuit part.
40. Pumped two-phase cooling system of aspect 39, the further pump being disposed at the third circuit part between the heat exchanger and the second portion of the second circuit part.
41. Pumped two-phase cooling system of any of aspects 37 to 40, the third circuit part connecting to the second circuit part between the heat exchanger and the evaporator.
42. Pumped two-phase cooling system of any of aspects 37 to 40, the third circuit part connecting to the second circuit part between the reservoir and the pump or between the pump and the heat exchanger.
43. Pumped two-phase cooling system of any of aspects 25 to 42, the third circuit part connecting to the second circuit part between the condenser and the reservoir.

### SHORT DESCRIPTION OF THE DRAWINGS

The subject-matter of the disclosure will be explained in more detail with reference to preferred exemplary embodiments which are illustrated in the attached drawings.

FIG. 1 is a schematic illustration of a pumped two-phase cooling system according to prior art.

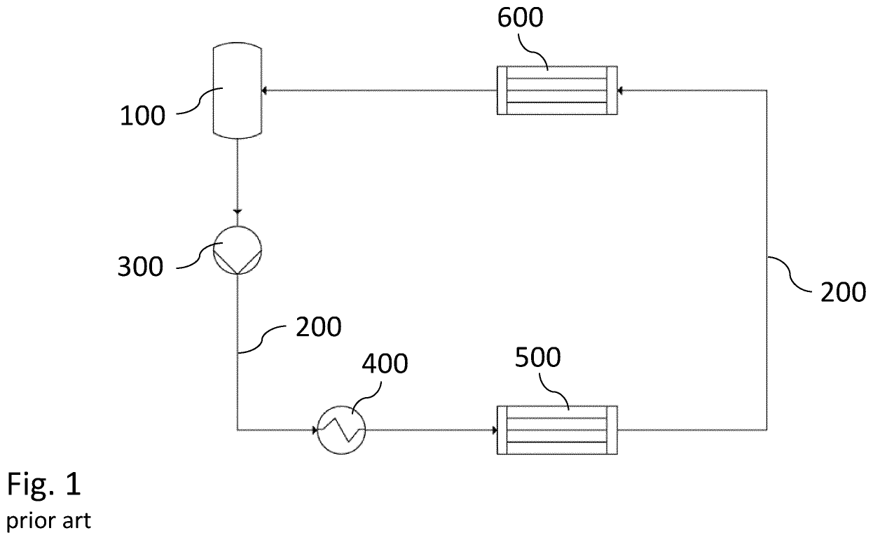

FIG. 2 is a schematic illustration of a pumped two-phase cooling system according to a first embodiment.

FIG. 3 is a schematic illustration of a pumped two-phase cooling system according to a second embodiment.

FIG. 4 is a schematic illustration of a pumped two-phase cooling system according to a third embodiment.

### DETAILED DESCRIPTION

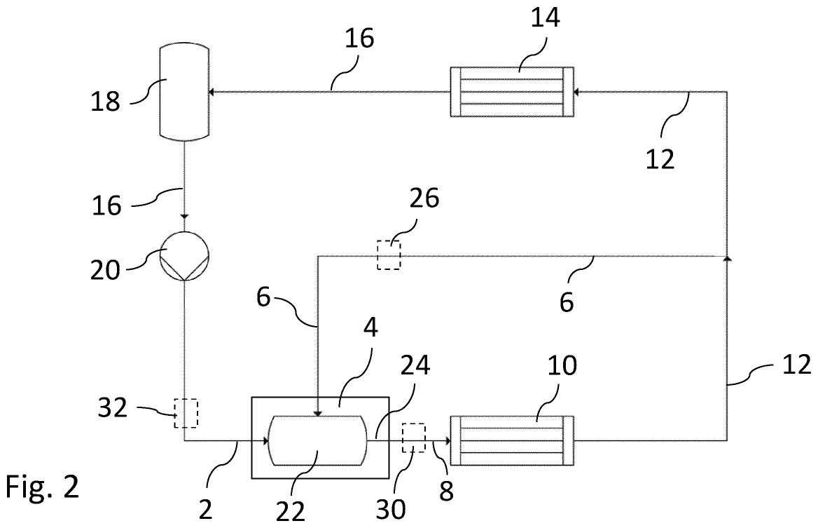

FIG. 2 is a schematic illustration of a pumped two-phase cooling system according to a first embodiment. The cooling system comprises a two-phase working fluid circuit for guiding a two-phase working fluid.

The system further comprises a pump 20, a preheater assembly 4, an evaporator 10, and a condenser 14. The pump 20 is configured to pump the working fluid through the circuit. Specifically, the system is configured such that the working fluid can be pumped by the pump 20 via the circuit through the evaporator 10 and through the condenser 14.

The system illustrated in FIG. 2 shows an example system having only one evaporator 10. However, the system may comprise a plurality of evaporators. These evaporators may, for example, be connected in series or in parallel.

Further, the system comprises a reservoir 18 for balancing the system.

The circuit comprises a first circuit section 2, a second circuit section 6, and a third circuit section 8. The first circuit section 2 is configured to guide a first portion of the working fluid to the preheater assembly 4. The second circuit section 6 is configured to guide a second portion of the working fluid to the preheater assembly 4. The third circuit section 8 is configured to guide a third portion of the working fluid from the preheater assembly 4 to the evaporator 10.

The first portion of the working fluid has first thermal characteristics comprising that the working fluid is in a liquid phase. The second portion of the working fluid has second thermal characteristics comprising that the working fluid is partly in a liquid phase and partly in a gaseous phase. The third portion of the working fluid has third thermal characteristics comprising that the working fluid is in a liquid phase.

The third thermal characteristics are based on the first and second thermal characteristics.

The preheater assembly 4 comprises a junction 22 configured to allow the first portion of the working fluid to mix with the second portion of the working fluid. In other words, the working fluid originating from the first circuit section 2 and the working fluid originating from the second circuit section 6 are mixed at the junction 22 within the preheater assembly 4. Consequently, the thermal energy of the working fluid leaving the preheater assembly 4, i.e. the third portion of the working fluid is based on or depends on the first thermal characteristics and the second thermal characteristics. The third thermal characteristics further depends on a first volumetric flow rate at which the first portion of the working fluid reaches the junction 22 and a second volumetric flow rate at which the second portion of the working fluid reaches the junction 22.

The preheater assembly 4 further comprises a coupling circuit section 24 that connects the junction 22 to the third circuit section 8 so that the working fluid can flow from the junction 22 into the third circuit section 8 via the coupling circuit section 24.

The preheater assembly 4 is configured to heat the working fluid to its saturation temperature or at least nearly to its saturation temperature.

The circuit further comprises a fourth circuit section 12 for guiding a fourth portion of the working fluid from the evaporator 10 to the condenser 14. In other words, the fourth circuit section 12 connects the evaporator 10 with the condenser 14 such that the working fluid can flow from the evaporator 10 to the condenser 14.

The second circuit section 6 is connected to the fourth circuit section 12. In other words, one end of the second circuit section 6 enters the preheater assembly 4 and the other, opposite end of the second circuit section 6 is fluidly connected to the fourth circuit section 12.

The circuit further comprises a fifth circuit section 16 for guiding a fifth portion of the working fluid from the condenser 14 to the first circuit section 2. In other words, the fifth circuit section 16 connects the condenser 14 with the first circuit section 2 such that the working fluid can flow from the condenser 14 to the first circuit section 2.

The reservoir 18 and/or the pump 20 may be disposed within the fifth circuit section 16, as exemplarily sketched in FIG. 2.

The preheater assembly 4 may comprise an electric heating device for heating the working fluid. The heating device may be disposed and arranged to heat the working fluid within the coupling circuit section 24, i.e. between the junction 22 and the evaporator 10. In this way, the working fluid can be heated by the electric heating device up to its or at least nearly to its saturation temperature if the working fluid downstream of the junction 22 does not yet have the desired temperature for entering the evaporator 10. This can be particularly advantageous during an initial phase after the system has been started up, as long as an average temperature of the working fluid is not yet at an equilibrium level.

The system may further comprise a valve 26 disposed within the second circuit section 6. The valve 26 may be configured to allow the working fluid to flow from the fourth circuit section 12 via the second circuit section 6 to the preheater assembly 4. The valve 26 may be configured to prevent the working fluid from flowing from the preheater assembly 4 via the second circuit section 6 to the fourth circuit section 12.

The valve 26 may further be configured to control a flow, i.e. a volumetric flow rate of the working fluid from the fourth circuit section 12 via the second circuit section 6 to the preheater assembly 4. In this way, an amount of thermal energy fed to the preheater assembly 4 by the working fluid within the second circuit section 6 can be adjusted.

The system may further comprise at least one temperature and/or pressure sensor device 30, 32 for measuring a temperature and/or a pressure of the working fluid. The at least one temperature and/or pressure sensor device 30, 32 may be disposed for example within the first circuit section 2 and/or within the third circuit section 8. A temperature or pressure measured by the temperature and/or pressure sensor device 30, 32 can be advantageously used for an improved control of the thermal characteristics of the working fluid.

Particularly, the valve 26 may be configured to be operated under use of a temperature and/or pressure information generated by the temperature and/or pressure sensor device 30, 32.

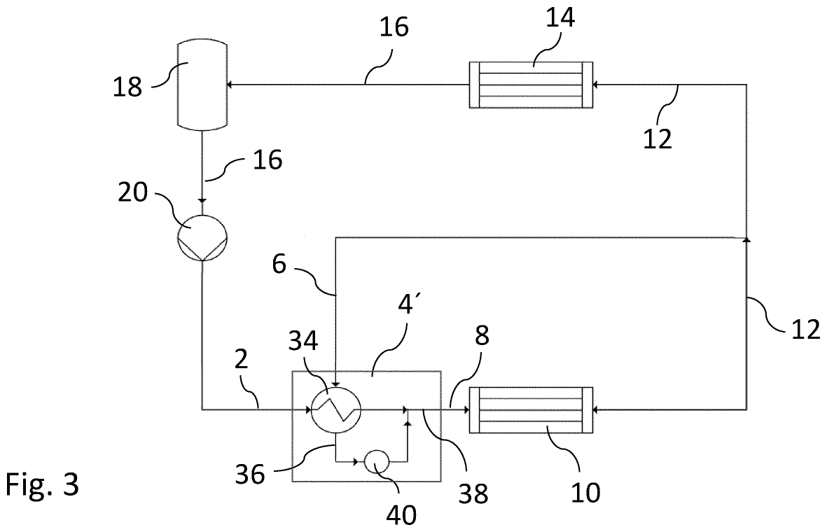

FIG. 3 is a schematic illustration of a pumped two-phase cooling system according to a second embodiment.

Unless otherwise stated below, the above description of the first embodiment also applies to the other embodiments. The reference signs are used in an analogous manner.

The preheater assembly 4′ according to the second embodiment comprises a heat exchanger 34 connected to the first circuit section 2 and to the second circuit section 6. The preheater assembly 34 is configured to exchange heat between the first portion of the working fluid and the second portion of the working fluid. The system further comprises an extension circuit section 36 for guiding the working fluid originating from the second circuit section 6, after it has passed through the heat exchanger 34, to a coupling circuit section 38 connecting the first circuit section 2 to the third circuit section 8.

Further, the system comprises an auxiliary pump 40 for pumping the working fluid from the extension circuit section 36 to the third circuit section 8.

The auxiliary pump 40 may be configured to be operated only when required. Due to the arrangement of the second circuit section 6 and the extension circuit section 36, it can be assumed that the auxiliary pump 40 in principle requires less energy compared to a corresponding pump according to prior art as described above.

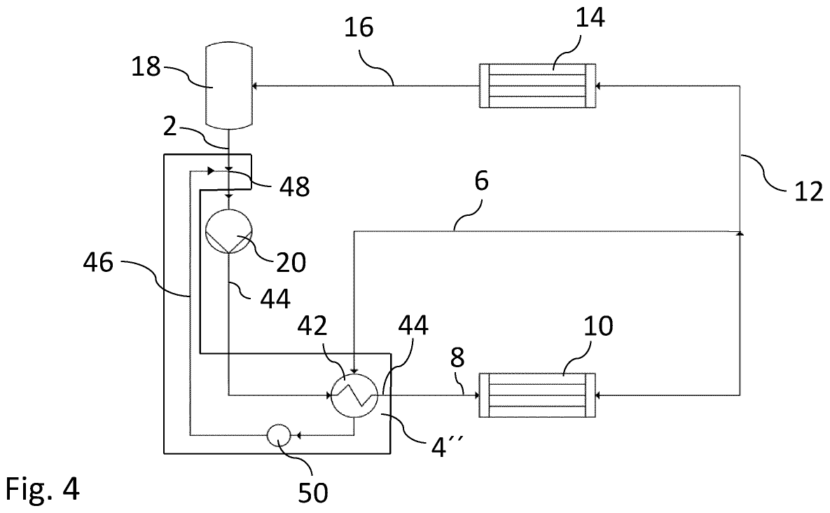

FIG. 4 is a schematic illustration of a pumped two-phase cooling system according to a third embodiment.

The preheater assembly 4″ according to the third embodiment comprises a heat exchanger 42 connected to the second circuit section 6 and to a coupling circuit section 44 connecting the first circuit section 2 to the third circuit section 8. The heat exchanger 42 is configured to exchange heat between the working fluid originating from the second circuit section 6 and the working fluid within the coupling circuit section 44.

The system further comprises an extension circuit section 46 for guiding the working fluid originating from the second circuit section 6, after it has passed through the heat exchanger 42, to the coupling circuit section 44 at a point 48 between the first circuit section 2 and the heat exchanger 42. The point 48 may be for example between the first circuit section 2 and the pump 2 or for example between the pump 20 and the heat exchanger 42. Alternatively, the extension circuit section may be configured to guide the working fluid originating from the second circuit section 6, after it has passed through the heat exchanger 42, to the reservoir 18.

The system further comprises an auxiliary pump 50 for pumping the working fluid from the extension circuit section 46 to the coupling circuit section 44 or to the reservoir 18. The auxiliary pump 50 may be configured to be operated only when required. Due to the arrangement of the second circuit section 6 and the extension circuit section 46, it can be assumed that the auxiliary pump 40 in principle requires less energy compared to a corresponding pump according to prior art as described above.

While the present disclosure has been described in detail in the drawings and forgoing description, such description is to be considered illustrative or exemplary and not restrictive. Variations to the disclosed embodiments can be understood and effected by those skilled in the art and practicing the claimed subject-matter, from a study of the drawings, the disclosure, and the appended claims. In the claims, the word “comprising” does not exclude other elements, and the indefinite article “a” or “an” does not exclude a plurality. The mere fact that certain elements or steps are recited in distinct claims does not indicate that a combination of these elements or steps cannot be used to advantage, specifically, in addition to the actual claim dependency, any further meaningful claim combination shall be considered disclosed.

1-15. (canceled)

16. A pumped two-phase cooling system, comprising
a two-phase working fluid circuit, having
a first circuit section for guiding a first portion of the working fluid to a preheater assembly, the first portion in the first circuit section having first thermal characteristics,
a second circuit section for guiding a second portion of the working fluid to the preheater assembly, the second portion in the second circuit section having second thermal characteristics, and
a third circuit section for guiding a third portion of the working fluid from the preheater assembly to at least one evaporator, the third portion in the third circuit section having third thermal characteristics based on the first and second thermal characteristics, and
a fourth circuit section for guiding a fourth portion of the working fluid from the at least one evaporator to a condenser, the second circuit section being connected to the fourth circuit section, wherein one end of the second circuit section enters the preheater assembly and the other, opposite end of the second circuit section is fluidly connected to the fourth circuit section.

17. The pumped two-phase cooling system of claim 16, the two-phase working fluid circuit further comprising a fifth circuit section for guiding a fifth portion of the working fluid from the condenser to the first circuit section, wherein the first portion of the working fluid originates from the fifth portion.

18. The pumped two-phase cooling system of claim 17, the fifth circuit section comprising a reservoir for the working fluid.

19. The pumped two-phase cooling system of claim 16, further comprising a pump for pumping the working fluid through the two-phase working fluid circuit.

20. The pumped two-phase cooling system of claim 16, further comprising a valve disposed within the second circuit section.

21. The pumped two-phase cooling system of claim 20, the valve being configured to allow the working fluid to flow from the fourth circuit section via the second circuit section to the preheater assembly and further being configured to prevent the working fluid from flowing from the preheater assembly via the second circuit section to the fourth circuit section.

22. The pumped two-phase cooling system of claim 20, the valve being configured to control a flow of the working fluid from the fourth circuit section via the second circuit section to the preheater assembly.

23. The pumped two-phase cooling system of claim 16, further comprising at least one temperature and/or pressure sensor device for measuring a temperature and/or a pressure of the working fluid, the at least one temperature and/or pressure sensor device being disposed within the first circuit section and/or within the third circuit section.

24. The pumped two-phase cooling system of claim 16, wherein the valve is configured to be operated under use of a temperature and/or pressure information generated by the temperature and/or pressure sensor device.

25. The pumped two-phase cooling system of claim 16, the preheater assembly comprising a junction configured to allow the first portion of the working fluid to mix with the second portion of working fluid.

26. The pumped two-phase cooling system of claim 16, the preheater assembly further comprising a heat exchanger connected to the first circuit section and to the second circuit section and being configured to exchange heat between the first portion of the working fluid and the second portion of the working fluid,
the system further comprising an extension circuit section for guiding the working fluid originating from the second circuit section, after it has passed through the heat exchanger, to a coupling circuit section connecting the first circuit section to the third circuit section.

27. The pumped two-phase cooling system of claim 26, further comprising an auxiliary pump for pumping the working fluid from the extension circuit section to the third circuit section.

28. The pumped two-phase cooling system of claim 16, the preheater assembly further comprising a heat exchanger connected to the second circuit section and to a coupling circuit section connecting the first circuit section to the third circuit section, the heat exchanger being configured to exchange heat between the working fluid originating from the second circuit section and the working fluid within the coupling circuit section,
the system further comprising an extension circuit section for guiding the working fluid originating from the second circuit section, after it has passed through the heat exchanger, to the coupling circuit section at a point between the first circuit section and the heat exchanger.

29. The pumped two-phase cooling system of claim 28, further comprising an auxiliary pump for pumping the working fluid from the extension circuit section to the coupling circuit section.
